(19) United States
(12) Patent Application Publication
(10) Pub. No.: US 2019/0312169 A1
(43) Pub. Date: Oct. 10, 2019

(54) PHOTODIODE AND METHOD OF MAKING THEREOF

(71) Applicant: Huaian Imaging Device Manufacturer Corporation, Huaian (CN)

(72) Inventors: Tienchi Ko, Huaian (CN); Shao Dong Liu, Huaian (CN)

(21) Appl. No.: 16/376,217

(22) Filed: Apr. 5, 2019

(30) Foreign Application Priority Data
Apr. 9, 2018 (CN) 201810308997.5

(51) Int. Cl. H01L 31/102; H01L 31/18; H01L 27/146

(52) U.S. Cl. CPC H01L 31/102; H01L 27/14643; H01L 31/18

(57) ABSTRACT

A photodiode in a CMOS image sensor and a method for making the photodiode are described. To make the photodiode, protrusions and trenches are alternately patterned on the surface of a semiconductor substrate. The protrusions and trenches are doped to form a first doped layer; and an upper portion of the first doped layer is doped to form a second doped layer, the first and second doped layers comprise dopants having opposite polarities. The photodiode further includes a dielectric layer on the second doped layer. A CMOS image sensor with the photodiode has an improved quantum efficiency and enhanced performance.

### CROSS REFERENCE TO RELATED APPLICATION

This application claims the benefits of priority to Chinese Patent Application No. CN 201810308997.5, entitled “Photodiode and Method of Making Thereof”, filed with CNIPA on Apr. 9, 2018, the contents of which are incorporated herein by reference in its entirety

### TECHNICAL FIELD

The present disclosure relates to the field of semiconductor sensor technology, and in particular, to CMOS image sensor and method of making thereof.

### BACKGROUND

Image sensors can detect optical images and convert the optical image information into a usable output signal and thereby enlarge the vision range of human eyes. A Complementary Metal Oxide Semiconductor (CMOS) image sensor is one type of image sensor which is manufactured based on a CMOS technology.

Photodiodes, used as photons to electrons conversion device, may be applied to CMOS image sensors. The basic imaging unit of a CMOS image sensor is referred to as a pixel. A CMOS image sensor configuration may include one photodiode and three or four MOS transistors, this configuration is referred to as a 3T type or a 4T type for short. The photodiode is configured to convert an optical signal into a corresponding current signal, and the MOS transistors are configured to read the current signals converted by the photodiode.

Referring to FIG. 1, FIG. 1 is a structural diagram of a backside illumination CMOS image sensor including a photodiode according to an existing technology. The backside illumination CMOS image sensor includes: a front-end structure 10 in which a photodiode 11 is formed, an auxiliary structure 13 and a dielectric layer 12 located on a front surface of the front-end structure 10. The auxiliary structure 13 is surrounded by the front-end structure 10 and the dielectric layer 12, and the refractive index of the auxiliary structure 13 is less than refractive indexes of the front-end structure 10 and the dielectric layer 12. A metal connection line layer 16 is further formed on the front surface of dielectric layer 12 of the front-end structure 10, and an optical filter 17 and a microlens 18 are formed on a back surface of the front-end structure 10.

However, when light is transmitted from the front-end structure 10 into the photodiode 11 at a large angle, because the auxiliary structure 13 is a planar structure so it does not deflect light, the transmitted light cannot get into the photodiode 11, therefore the transmitted light effectively entering the photodiode 11 is reduced, and optical-to-electrical conversion efficiency of the photodiode is also reduced.

### SUMMARY

The photodiode in a CMOS image sensor and a method for making the photodiodes is described. The photodiode includes a semiconductor substrate, wherein protrusions and trenches are alternately patterned on a surface of the semiconductor substrate; the trenches and protrusions are doped to form a first doped layer; and an upper portion of the first doped layer is doped to form a second doped layer, wherein the first and second doped layers comprise opposite polarity dopants. The photodiode further includes a dielectric layer on the second doped layer. The CMOS image sensor with the photodiode has an improved quantum efficiency and enhanced performance

Optionally, the protrusions each has a trapezoid-like structure.

Optionally, an inclined surface each of the protrusions has inclined sidewalls, wherein the inclined sidewalls form angle with the substrate surface ranging from 30 to 90 degrees.

Optionally, a height of the protrusions is 1500 Å to 2000 Å.

Optionally, the first doped layer is N-doped, and the second doped layer is P-doped.

Optionally, the first doped layer is doped with a first ion implantation process.

Optionally, a depth of the first doped layer ranges from 100 Å to 1000 Å, and a depth of the second doped layer ranges from 100 Å to 1000 Å.

Optionally, a dielectric layer is disposed on the second doped layer.

The dielectric layer is a silicon oxide layer, having a thickness ranging from 100 Å to 1000 Å.

The present disclosure further provides a method for fabricating the photodiode: it includes providing a semiconductor substrate, comprising protrusion and trenches alternately patterned on a surface of the semiconductor substrate; performing a first ion implantation process to form a first doped layer on the surface of the semiconductor substrate; and performing a second ion implantation process to an upper portion of the first doped layer, to form a second doped layer on the first doped layer, wherein the first doped layer has a doping type opposite to a doping type of the second doped layer.

Optionally, the protrusions and the trenches are formed through a litho/etching process.

Optionally, the first ion implantation process performs N doping, and the second ion implantation process performs P doping.

The present disclosure further provides a semiconductor device, comprising a photodiode, a MOSFET, and a floating-gate diode, wherein the photodiode is used in a CMOS image sensor.

### BRIEF DESCRIPTION OF THE DRAWINGS

FIG. 1 is a structural diagram of a conventional backside illumination CMOS image sensor comprising photodiodes.

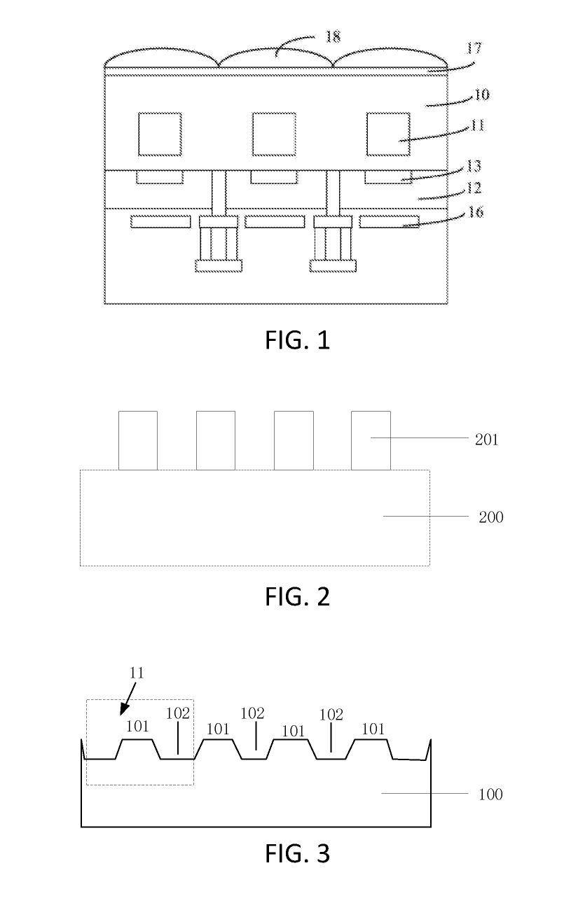

FIG. 2 and FIG. 3 are structural diagrams of semiconductor substrates for CMOS image sensors according to the present disclosure.

FIGS. 4 to 8 are cross sectional views of structural diagrams after each step in the making of the CMOS photodiodes according to the present disclosure.

FIG. 9 is a flowchart of the process of making the photodiodes disclosed in FIGS. 2-8.

FIG. 10 is a flowchart of another process of making photodiodes according to the present disclosure.

### DETAILED DESCRIPTION OF THE PREFERRED EMBODIMENTS

The present disclosure is described in detail below with reference to the embodiments and the accompanying drawings. It should be understood that the following content may provide different embodiments for achieving the purpose of the disclosure of this application and obtaining beneficial technical effects or preferred embodiments therein. However, a person skilled in the art can still make modifications to the embodiments of the present disclosure according to the disclosed techniques or common knowledge and can still achieve beneficial effects of the present disclosure. Therefore, the following contents are merely instances and are not intended to limit the present disclosure.

In addition, reference numbers and/or characters may be repeated in a plurality of instances in the present disclosure. Such repetitions are only for the purpose of simplification and clearness and do not indicate relationships between the discussed multiple embodiments and/or configurations.

In addition, in the following descriptions, forming a first component above or on a second component not only may comprise an embodiment formed by the first component and the second component in a direct contact manner but also may further comprise an embodiment that an extra component may be formed between the first component and the second component, so that the first component may not be in direct contact with the second component. It should be noted that in a case of no conflict, the embodiments in this application and features in the embodiments can be mutually combined.

The present disclosure provides a photodiode, comprising: a semiconductor substrate, protrusions and trench are patterned on a surface of the semiconductor substrate; a first doped layer, including the protrusions and the trench adjacent to the protrusions; and a second doped layer, the second doped layer is the upper portion of the first doped region further doped with a second dopant, where doping types of the first doped layer (relating to positive or negative doping) is opposite to that of the second doped layer. The semiconductor substrate may be a silicon wafer or a silicon-germanium wafer. In some embodiments, the semiconductor substrate may be a compound semiconductor, such as silicon carbide, gallium arsenide, and indium arsenide or indium phosphide. Further, in some other embodiments, the semiconductor substrate is silicon on insulator (SOI) or an epitaxial layer on a silicon wafer. In some embodiments, the semiconductor substrate may be a semiconductor compound, such as silicon germanium, silicon germanium carbide, gallium arsenide phosphide, or indium gallium phosphide.

More specifically, in this embodiment, the semiconductor substrate is P-type silicon, which is realized by doping boron in a silicon substrate, for example using an ion implantation or diffusion process to realize uniform doping. The doping concentration in the semiconductor substrate ranges from 10¹⁵ cm⁻³ to 10¹⁸ cm⁻³. When performing the doping process, energy of doped ions and the doping concentration may be selected according to the circumstances, and the doped ions used is, for example, boron ions. To improve optical-to-electrical conversion efficiency of the photodiodes, a surface of the semiconductor substrate is provided with protrusions and trench that are patterned. An objective of forming the protrusions and the trenches is to create inclined angles on the sidewalls of the photodiodes to increase light entering the photodiodes. In addition, a first doped layer and a second doped layer are formed on the protrusions and trenches to increase internal reflection of the light rays entering the photodiodes. Thereby quantum efficiency of the photodiode is improved and performance of the CMOS image sensor enhanced.

The protrusions and trenches are alternately patterned. Optionally, the protrusion is formed by etching the surface of the semiconductor substrate. Limited by most etching a protrusion is commonly wider at its bottom than its top, like a trapezoid. There is a non-zero angle between the protrusion's sidewalls and the substrate surface. In a preferred embodiment, the angle ranges from 90 degrees to 150 degrees. The trapezoid-like cross section of the protrusion in this embodiment makes it into a shape of a cuboid. The height of the cuboid protrusion is 1500 Å to 2000 Å.

The photodiode surface is disposed with a first doped layer. In an embodiment of the present disclosure, the semiconductor substrate is N-doped, and the first doped layer is P-doped, for example, the dopants can be phosphorous ions or arsenic ions etc. Optionally, the concentration of the dopants ranges from 10¹⁵ cm⁻³ to 10¹⁸ cm⁻³, and the depth of the dopants ranges from 100 Å to 1000 Å.

Further, the photodiode is disposed with a second doped layer on the first doped layer, the first doped layer has a dopant type opposite to the dopants' type in the second doped layer. The first doped layer and the second doped layer compose a PN junction of the photodiode. An ion implantation depth of the second doped layer ranges from 100 Å to 1000 Å.

When the first doped layer is P-doped, the second doped layer is N-doped, and the dopants are, for example, boron, gallium, or indium etc. Optionally, the concentration of the implanted ions ranges from 10¹⁵ cm⁻³ to 10¹⁸ cm⁻³.

In the photodiode structure, the first doped layer and the second doped layer both conform to the protrusions and trenches, thus increasing size of the PN junction which is formed from the contact area of first and second doped layers. The sidewalls of the protrusions form an inclination angle with the substrate. Therefore, the acceptance angle of the photodiode to light rays is increased, because light rays at high incident angles may enter the photodiode while they are outside the light acceptance angle if the photodiode has a flat surface. Secondly, the internal reflection of light rays inside the diode is also increased, thereby improving quantum efficiency of the photodiode and improving photosensitivity performance of the photodiode.

Optionally, the photodiode further comprises a dielectric layer on the second doped layer. The dielectric layer is, for example, a silicon oxide layer, having a thickness ranging from 100 Å to 1000 Å, formed by chemical vapor deposition, the dielectric layer passivates the photodiode surface.

This embodiment further provides a method for making a photodiode, comprising:

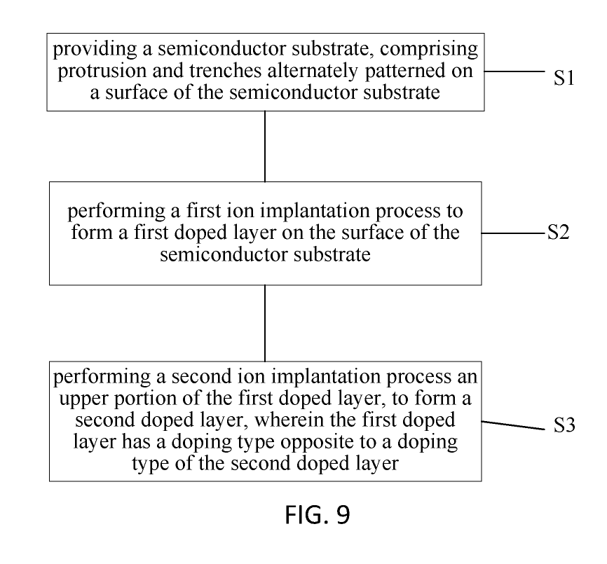

Referring to FIG. 9, step S1: providing a semiconductor substrate, a surface of the semiconductor is alternately patterned with protrusions and trenches. An exemplary structure of the semiconductor substrate described in this step is shown in FIG. 3.

The semiconductor substrate 100 may be an element semiconductor, such as silicon, or germanium. In some embodiments, the semiconductor substrate 100 may be a compound semiconductor, such as silicon carbide, gallium arsenide, indium arsenide or indium phosphide. Further, in some other embodiments, the semiconductor substrate 100 may be silicon on insulator and/or an epitaxial layer. In some embodiments, the semiconductor substrate 100 may be an alloy semiconductor, such as silicon germanium, silicon germanium carbide, gallium arsenide phosphide, or indium gallium phosphide. Further, in this embodiment, the semiconductor substrate comprises P-type silicon, which is realized by doping a silicon substrate, for example ion implantation or diffusion process. The doping ions are, for example, boron ions. A doping concentration ranges from 10¹⁵ cm⁻³ to 10¹⁸ cm⁻³.

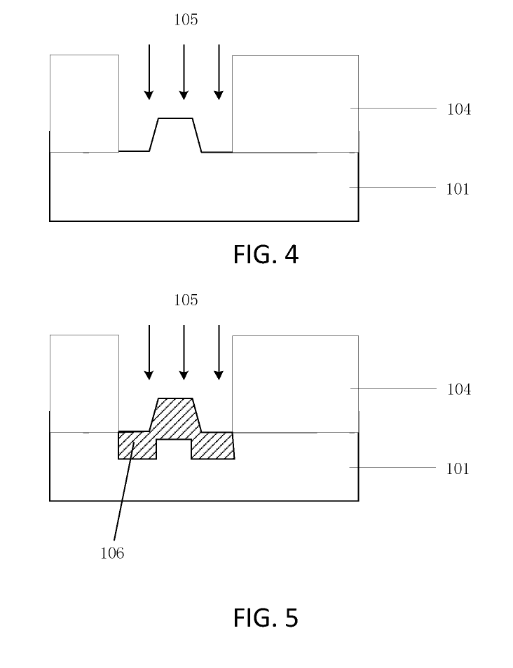

In an optional embodiment, protrusions 101 and trenches 102 are alternatively patterned on the surface of the semiconductor substrate 100. Referring to FIG. 2, a substrate 200 is first provided, and the material of the substrate 200 is the same as the material of the semiconductor substrate 100, it is not described in detail herein. A photoresist pattern 201 is formed on a surface of the substrate 200, and then the photoresist pattern 201 is used as a mask to perform the litho/etching process, etching is performed to a depth, that is, the trench 102 is formed in the substrate 200, afterward, the photoresist pattern 201 is removed, and the protrusion 101 is formed at a part corresponding to the position of the photoresist pattern. The etching process is, for example, plasma etching, and an angle between an inclined surface of the protrusion 101 and the trench 102 may be controlled by controlling processes such as the type of etching ions, a pressure of a reaction chamber during etching, a flow of etching ions, and an etching angle.

Optionally, the protrusion 101 has commonly a trapezoid cross section. In addition, when the angle between the s side wall surface of the protrusion and the substrate surface is 90 degrees, the protrusion has a shape of a cuboid. Optionally, a height difference of the protrusion formed by etching is 1500 Å to 2000 Å.

The angle between the inclined surface of the protrusion 101 and the trench 102 has direct effect on performance of the formed photodiode. In a preferred embodiment, the angle ranges from 90 degrees to 150 degrees. A larger angle indicates a larger size of a bottom edge of the protrusion 101 and thus a larger range of an entrance for light to be incident in the protrusion 101. However, if the angle is excessively large, a reflection angle of reflected light in the protrusion increases accordingly, and consequently, poor light concentration occurs to the photodiode. If the angle is excessively small, the range of the acceptance incident angle for light into the protrusion 101 decreases. However, internal reflection to lose light from the protrusion 101 also decreases. Therefore, the photodiode receives more light. Therefore, in this embodiment, preferably, the angle ranges from 90 degrees to 150 degrees.

Because the protrusions and the trenches are provided on the surface of the semiconductor substrate, the first doped layer and the second doped layer conform to the photodiode so also maintain the same inclination angle with the substrate surface. The acceptance incident angle of light rays of the photodiode is increased, internal light rays loss is reduced, thereby quantum efficiency of the photodiode is improved and performance of the CMOS image sensor is enhanced.

In an exemplary embodiment of the present disclosure, the etching processes are: etchant can be chlorine ions, the pressure of the reaction chamber during etching ranges from 50 mtorr to 80 mtorr, the flow of etching ions ranges from 50 sccm to 1000 sccm, and the incident angle of the etching ions is about 30 degrees to 80 degrees from substrate surface norm. The height the protrusion 101 formed by etching is 1500 Å to 2000 Å.

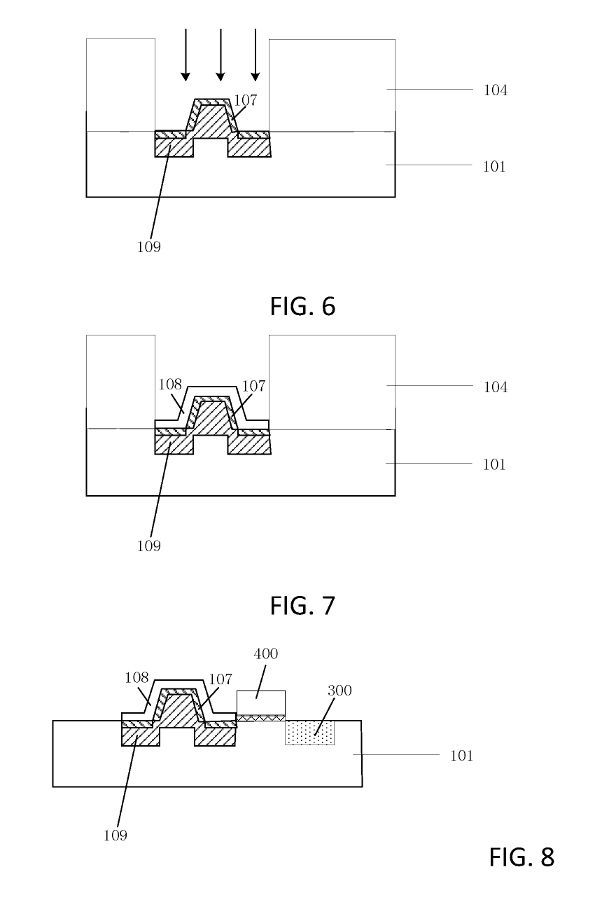

After the etching process is completed, the semiconductor substrate 100 is formed by the substrate 200. In subsequent accompanying drawings, for clearness of the accompanying drawings and ease of description, some structures of an area 11 in FIG. 3 are selected as an exemplary description. In addition, FIGS. 4 to 8 schematically describe subsequent processes performed in the area 11.

Referring to FIGS. 4 to 5, and FIG. 9, step S2: with a photoresist layer 104 on the substrate surface, performing a first ion implantation process 105, so that the protrusions and the trenches adjacent to the protrusion of the semiconductor substrate form a first doped layer 106. When the semiconductor substrate is N-doped, the first doped layer 106 is P-doped. An ion injected in the first ion implantation process is, for example, phosphorous ions and arsenic ions. Optionally, the concentration of the injected ions ranges from 10¹⁵ cm⁻³ to 10¹⁸ cm⁻³, and energy of injection of the doping ions ranges from 50 Kev to 100 Kev. The depth of ion implantation ranges from 100 Å to 1000 Å. The concentration of the doping ions in the formed first doped layer 106 ranges from 10¹⁵ cm⁻³ to 10¹⁸ cm⁻³.

After the first ion implantation process is performed, annealing treatment is preferably performed. On one hand, damage to crystal lattices in the first ion implantation process is repaired, and on the other hand, injected ions in the first ion implantation process are further uniformly diffused. In an optional implementation of this application, process conditions for the annealing are: the annealing temperature ranging from 900° C. to 1200° C., and the annealing time ranging from 30 s to 60 s.

Referring to FIG. 6 and FIG. 9, step S3: performing a second ion implantation process to an upper portion of the first doped layer 106, to form a second doped layer 107, the first doped layer 106 has a doping type opposite to the second doped layer 107. The second doped layer overlaps the first doping layer.

The first doped layer 106 includes the upper portion and the lower portion 109. The upper portion is performed with the second ion implantation process to form a second doped layer 107 which overlaps the upper portion of the first doping layer. The thickness of the second doped layer 107 ranges from 100 Å to 1000 Å. The lower portion 109 may have a thickness the same as that of the second doped layer. In an optional embodiment of the present disclosure, the semiconductor substrate is N-doped, and the first doped layer 106 is P-doped. Therefore, the second doped layer 107 is N-doped. An ion injected in the second ion implantation process is, for example, a boron ion, gallium, and indium. Optionally, the concentration of the injected ions ranges from 10¹⁵ cm⁻³ to 10¹⁸ cm⁻³, and energy of injection of the doping ions ranges from 50 KEV to 100 KEV. The depth of ion implantation ranges from 100 Å to 1000 Å. The concentration of the doping ions in the formed second doped layer 107 ranges from 10¹⁵ cm⁻³ to 10¹⁸ cm⁻³.

After the second ion implantation process is performed, annealing treatment is preferably performed. On one hand, damage to crystal lattices in the ion implantation process is repaired, and on the other hand, implanted ions in the second ion implantation process are further uniformly diffused. In an optional implementation of this application, process conditions for the annealing are: the annealing temperature ranging from 900° C. to 1200° C., the annealing time ranging from 30 s to 60 s.

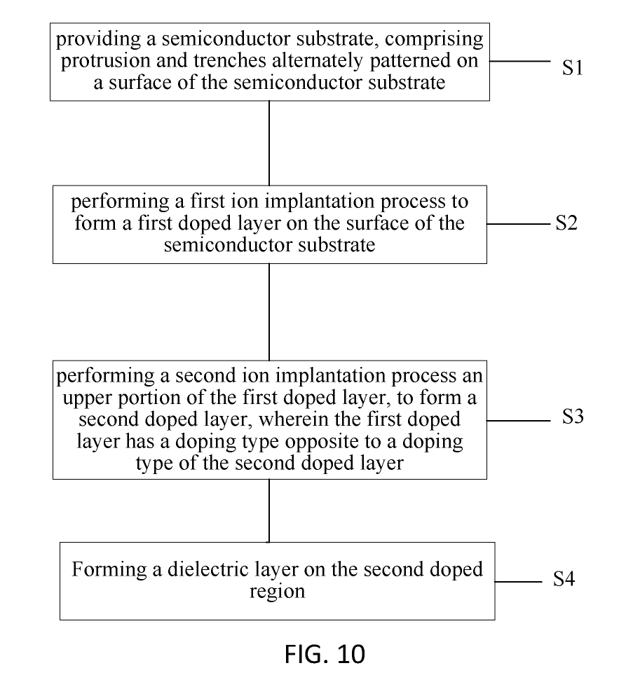

Referring to FIG. 10, FIG. 10 is a flowchart of another process embodiment of making a photodiode. An exemplary implementation of this application further comprises a process of step S4: forming a dielectric layer 108 on the second doped layer 107. The dielectric layer is, for example, a silicon oxide layer, having a thickness ranging from 100 Å to 1000 Å, formed by chemical vapor deposition, and the dielectric layer 108 in the photodiode structure is used to passivate the device from external environment.

In addition, a refractive index for light in the second doped layer 107 is less than that of the dielectric layer 108. When light is incident on the dielectric layer 108 from the second doped layer 107, light refraction angle reduces at the interface. This might decrease light loss internally Quantum efficiency of the photodiode and performance of the CMOS image sensor comprising the photodiode are improved.

Referring to FIG. 8, optionally, an MOSFET 400 and a floating-gate diode 300 are fabricated on the semiconductor substrate.

Although in the present disclosure, preferred implementations are disclosed as above, the implementations are not intended to limit the present disclosure. Any person skilled in the art can make possible variations and modifications to the technical solutions of the present disclosure by using the foregoing disclosed method and technical content without departing from the spirit and scope of the present disclosure. Therefore, any content that does not depart from the technical solutions of the present disclosure shall fall within the protection scope of the technical solutions of the present disclosure according to any simple modification, equivalent change, and alteration made to the foregoing implementations according to the technical essence of the present disclosure.

What is claimed is:

1. A photodiode, comprising:
a semiconductor substrate, wherein protrusions and trenches are alternately patterned on a surface of the semiconductor substrate;
a first doped layer disposed on the protrusions and trenches; and
a second doped layer formed on an upper portion of the first doped layer, wherein the first and second doped layers comprise opposite polarity dopants.

2. The photodiode according to claim 1, wherein the protrusions each has a trapezoid-like structure.

3. The photodiode according to claim 2, wherein an inclined surface each of the protrusions has inclined sidewalls, wherein the inclined sidewalls form angle with the substrate surface ranging from 30 to 90 degrees.

4. The photodiode according to claim 1, wherein a height of the protrusions is 1500 Å to 2000 Å.

5. The photodiode according to claim 1, wherein the first doped layer is N-doped, and the second doped layer is P-doped.

6. The photodiode according to claim 1, wherein the first doped layer is doped with a first ion implantation process.

7. The photodiode according to claim 1, wherein a depth of the first doped layer ranges from 100 Å to 1000 Å, and a depth of the second doped layer ranges from 100 Å to 1000 Å.

8. The photodiode according to claim 1, wherein the photodiode further comprises a dielectric layer on the second doped layer.

9. The photodiode according to claim 8, wherein the dielectric layer is a silicon oxide layer having a thickness ranging from 100 Å to 1000 Å.

10. A method for fabricating a photodiode, comprising:
providing a semiconductor substrate, comprising protrusions and trenches alternately patterned on a surface of the semiconductor substrate;
performing a first ion implantation process to form a first doped layer on the surface of the semiconductor substrate; and
performing a second ion implantation process to an upper portion of the first doped layer, to form a second doped layer, wherein the first doped layer has a doping type opposite to a doping type of the second doped layer.

11. The method for fabricating the photodiode according to claim 10, wherein the protrusion each has a trapezoid-like structure.

12. The method for fabricating the photodiode according to claim 10, wherein sidewalls of the protrusions form an inclined angle with the surface of the semiconductor substrate ranging from 30 to 90 degrees.

13. The method for fabricating the photodiode according to claim 10, wherein a height of the protrusions is 1500 Å to 2000 Å.

14. The method for fabricating the photodiode according to claim 10, wherein the alternating protrusions and the trenches are patterned by a lithography and an etching process.

15. The method for fabricating the photodiode according to claim 10, wherein the first ion implantation process applies N doping, and the second ion implantation process applies P doping.

16. The method for fabricating the photodiode according to claim 10, wherein a depth of the first doped layer ranges from 100 Å to 1000 Å, and a depth of the second doped layer ranges from 100 521 to 1000 Å.

17. The method for fabricating the photodiode according to claim 10, further comprising: forming a dielectric layer on the second doped layer.

18. The method for fabricating the photodiode according to claim 17, wherein the dielectric layer is a silicon oxide layer, having a thickness ranging from 100 Å to 1000 Å.

19. A semiconductor device, comprising a photodiode, a MOSFET, and a floating-gate diode, wherein the photodiode comprises:
a semiconductor substrate, wherein protrusions and trenches are alternately patterned on a surface of the semiconductor substrate;
a first doped layer disposed on the protrusions and trenches; and
a second doped layer formed on an upper portion of the first doped layer, wherein the first and second doped layers comprise opposite polarity dopants.
